(19) United States
(12) Patent Application Publication
(10) Pub. No.: US 2020/0303567 A1
(43) Pub. Date: Sep. 24, 2020

(54) Boosting solar cells photoelectric effectiveness with gold vapour or nanoparticles. Solar panel production employing mass newspaper-style printing technology would speed up production and lower the cost of producting panels. This process would be most beneficial to thin film solar panels that are made by depositing a thin film photovoltic material onto backing material

(71) Applicant: Jan Lepik, Vancouver (CA)

(72) Inventor: Jan Lepik, Vancouver (CA)

(21) Appl. No.: 16/501,307

(22) Filed: Mar. 22, 2019

(51) Int. Cl. H01L 31/0216

(52) U.S. Cl. CPC H01L 31/02167

(57) ABSTRACT

This patent employs innovative scientific ideas for human betterment. These technologically more efficient solar panels will help to change the way we generate electricity. A thin transparent photovoltaic film on windows could electrify cities. Similarly a solar film on airplane wings and bodies, truck trailers, delivery vans, and other moving vehicles could recharge their batteries while moving. Thin solar cells in roads and pavements can generate power and charge electric vehicles using cable-free induction energy. Thus, by shifting to a renewable energy source such as solar, the greenhouse gas emissions produced by transportation would be greatly reduced.

### BACKGROUND OF THE INVENTION (SCIENCE)

The photoelectric effect occurs when light shining down on a metal surface causes a small electric current to be produced. This happens because the energy photon present in the light knocks electrons from their atoms on the surface.

Metals are ductile rather than brittle because with few outer-shell electrons, solid metal is effectively an array of atomic nuclei filled by a “gas” of loosely bonded electrons. Metals bend rather than snap because this electron gas lets inter-atomic bonds stretch, break, and then re-form with new partners. The high mobility of electron gas is also responsible for the electrical and thermal conductivity of metals.

In 1905, Albert Einstein mathematically described the photoelectric effect as the absorption of photons and the emission of electrons from a surface by the action of light, for which discovery he received the Nobel Prize in Physics in 1921. Furthermore, Philipp Lenard, winner of the Nobel Prize in Physics in 1905, measured the maximal kinetic energy of the emitted electrons and found that it is independent on the intensity of light and is determined solely by the frequency of the light and the material-dependent threshold frequency. Blue light has a wavelength of between 420 and 450 nanometers. Each blue light photon carries enough energy to dislodge an electron. Dr. Lawrence M. Krauss, Foundation Professor and Director of the Origins Project at Arizona State University, there are roughly one billion photons in the microwave background for every photon in the universe. With the plentiful supply of photons in the universe, the energy produced by a solar panel is determined to a great extent by the number of available electrons and the material threshold frequency of the element.

A research paper published by the University of Toronto titled “Jointly Tuned Plasmonic-Excitonic Photovoltaics Using Nanoshells” by Professor Ted Sargent and co-authored by Assistant Professor Susanna Thon and their research group, claims to have found gold's capacity to increase the efficiency of solar cells. Since they regarded gold as not an economical metal to use, they turned to cheaper alternatives. Yuri Oganessian, researcher of the Joint Institute for Nuclear Research, Russia, has performed several studies with the gold atom on its' direct relativistic effect and indirect relativistic effect. In gold, the relativistic contraction lowers the energy of the s orbitals, even as it raises the energy of the d orbitals, thus narrowing the gap between the levels. Now the transition requires less energy—exactly that carried by a photon in the blue part of the spectrum. Now gold's electrons from the d-block orbit when struck by a photon of the blue wave length, will undergo a quantum transition. By absorbing the photon's energy, the electron will jump from the d orbit to the valence s orbit above it and be available to produce electricity.

Gold's atom electron filling order: 1s²2s²2p⁶3s²3p⁶3d¹⁰4s²4p⁶4d¹⁰5s²5p⁶4f¹⁴5d¹⁰6s¹

Today there are two main types of crystalline silicon solar panel technology: monocrystalline and polycrystalline. In addition, there are thin film solar panels that are generally less efficient than crystalline panels. Solar panel efficiency refers to the ratio of output power to input power.

In general, the more efficient a panel is, the more it usually costs. Whether you choose monocrystalline, polycrystalline or thin film solar panels usually depends on the space available for the installation, budget and aesthetics.

While the solar-powered aircraft Solar Impulse 2 had monocrystalline silicon solar cells 1.35 mm thick with an efficiency of 23%, transparent ultra-thin solar cells 0.001 mm thick film are able to harvest only 1% of the available solar energy. Improving the efficiency of all types of solar cells would make them more practical for all applications. Plus higher efficiency solar cells would bring down the cost of producing electricity since the installation would be smaller.

### BRIEF SUMMARY OF THE INVENTION

Experimentation done at the University of Toronto, Canada by Professor Ted Sargent and Assistant Professor Susanna Thon discovered that by embedding gold nanoshells on photovoltaics, it increased their efficiency. But since they assumed that gold is not an economical metal for solar cells, they dropped it to look for cheaper alternatives. At the time, gold was more costly, approximately $1,900 per ounce. Currently gold is approximately $1,450 per ounce.

Adding the gold atom to all the different types of photovoltaic cells would greatly increase the electron content in the valence or outer orbit to produce electricity. With the gold atom, the d orbit electrons will quantum jump to the S valence orbit by the photoelectric effect from the blue light photon.

Similarly a technique for spray-coating the photovoltaic material onto a moving surface would speed up the process and lower the cost.

### SPECIFICATION

FIG. 1: The drawing illustrates the design of a very basic newspaper sort off-set printing press. The small top rollers will wet the large printing roller with the subject matter, which it then deposits onto the backing material. By substituting thin film solar panel substances for ink, thin film solar panels could be printed just as readily as newspaper. All the required materials to manufacture the boosted thin film solar panels would be initially procured from outside suppliers.

FIG. 2: This sketch shows a simple direct roller printing press. Before electricity was available in small western U.S. towns, this type of printing press was used to manually print newspapers. Similar basic technology can be applied to print thin film solar panels and by doubling up the rollers, it is possible to boost efficiency by depositing two ingredients simultaneously.

FIG. 3: A minimal drawing of a simple furnace to heat gold to 2,840° C. the vapor state and deposit this gold vapor onto the moving photoelectric surface.

### BRIEF DESCRIPTION OF THE DRAWINGS

FIG. 1: In the illustration, the small rollers on top will wet the large transferring roller with both thin film photovoltaic material and gold particle solution to increase the photovoltaic effect, which describes solar cells' ability to produce voltage and current when exposed to sunlight. The large transfer roller will deposit this compound mixture onto the backing material. These thin film solar panels would roll off the assembly line as if they were coming off a printing press.

FIG. 2: The sketch shows a simple direct printing press, which technology can be applied to manufacture thin film solar panels. Doubling up the rollers and having the first one deposit photovoltaic material and the second one deposit a gold particle solution, which will increase the thin film's photovoltaic effect, onto backing material. Then these thin film solar panels would be manufactured as if they were coming off a printing press.

FIG. 3: Producing gold vapor by heating gold to 2,840° C. in a furnace and ejecting this gold vapor onto thin film photovoltaic material. By depositing gold atoms onto the thin film photovoltaic material, its photovoltaic effect is increased from the additional golds' electrons.

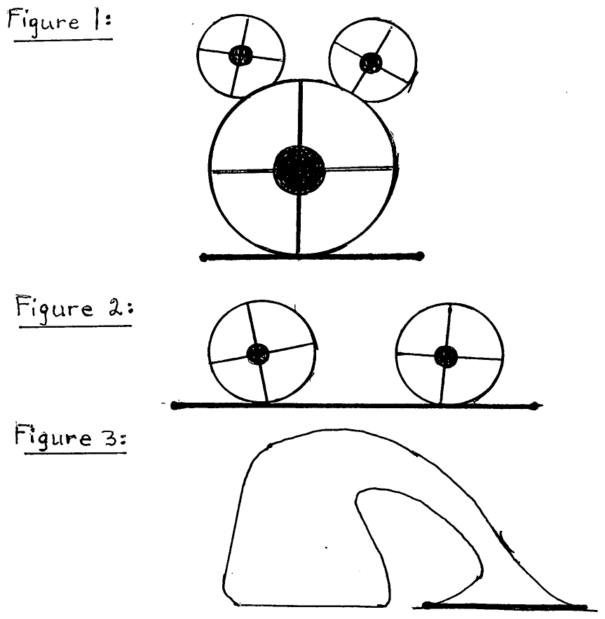

1. Attaching gold atoms to photovoltaic material to boost its electrical yield.

2. Having boosted thin film panels roll off an assembly line, as if they were coming off a printing press, would greatly speed up their production.

3. Gold boosted solar panels mounted on electrical vehicles will help to increase their range.
